(19) United States
(12) Patent Application Publication
(10) Pub. No.: US 2021/0025497 A1
(43) Pub. Date: Jan. 28, 2021

(54) SUPPORT MEMBER

(71) Applicant: VALQUA, LTD., Tokyo (JP)

(72) Inventors: Kazuaki TSUJI, Tokyo (JP); Takafumi SAKURAI, Sunnyvale, CA (US)

(21) Appl. No.: 16/934,322

(22) Filed: Jul. 21, 2020

(30) Foreign Application Priority Data
Jul. 26, 2019 (JP) 2019-137858

(51) Int. Cl. F16J 15/46; F16J 15/06; F16J 15/54; F16J 15/26

(52) U.S. Cl. CPC F16J 15/46; F16J 15/062; F16J 15/3248; F16J 15/26; F16J 15/54

(57) ABSTRACT

Provided is a support member attachable to a groove formed in an annular shape in a transport base, and the support member is to be attached to the groove for supporting an object to be transported. The support member includes: a held portion to be held in the groove; and a support portion formed in an annular shape for supporting the object to be transported at a position separated from the transport base with the held portion held in the groove. The held portion is pivotable in the groove to cause the support portion to incline with respect to the transport base.

### BACKGROUND OF THE INVENTION

### Field of the Invention

The present invention relates to a support member.

### Description of the Background Art

Japanese Patent Laying-Open No. 2019-39446 (hereinafter referred to as “Patent Document 1”) for example discloses a seal member that supports a precision member such as wafer on a casing. The casing has a groove formed in an annular shape. The seal member is formed in an annular shape. The seal member includes an attachment portion to be received in the groove, a seal portion formed inside the attachment portion in the radial direction of the attachment portion, and a connecting portion connecting the attachment portion to the seal portion. The seal portion includes an upper surface formed in an arc shape and a lower surface formed in an arc shape. The upper surface supports the precision member.

### SUMMARY OF THE INVENTION

Regarding the seal member disclosed in Patent Document 1, if an object to be transported such as wafer is inclined with respect to a transport base, contacts between the seal member and the object to be transported are reduced, and accordingly the supporting state in which the seal member is supporting the object to be transported may become unstable.

An object of the present invention is to provide a support member that can stabilize its state of supporting the object to be transported, when the object is inclined with respect to the transport base.

A support member according to an aspect of the present invention is a support member attachable to a groove formed in an annular shape in a transport base, and the support member is to be attached to the groove for supporting an object to be transported. The support member includes: a held portion to be held in the groove; and a support portion formed in an annular shape for supporting the object to be transported at a position separated from the transport base with the held portion held in the groove. The held portion is pivotable in the groove to cause the support portion to incline with respect to the transport base.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a support member in a first embodiment of the present invention.

FIG. 2 is a cross-sectional view along a line II-II in FIG. 1.

FIG. 3 is a cross-sectional view along a line III-III in FIG. 1.

FIG. 4 is a cross-sectional view of the support member and a transport base shown in FIG. 1.

FIG. 5 is a cross-sectional view schematically showing a state in which an object to be transported is slightly inclined with respect to the transport base.

FIG. 6 is a cross-sectional view schematically showing a state in which the object to be transported is further inclined with respect to the transport base as compared with the state shown in FIG. 5.

FIG. 7 is a plan view schematically showing a support member in a second embodiment of the present invention.

FIG. 8 is a cross-sectional view along a line VIII-VIII in FIG. 7.

FIG. 9 is a cross-sectional view along a line IX-IX in FIG. 7.

FIG. 10 is a cross-sectional view of the support member and a transport base shown in FIG. 7.

### DESCRIPTION OF THE PREFERRED EMBODIMENTS

Embodiments of the present invention are described with reference to the drawings. In the drawings referenced below, the same or corresponding members are denoted by the same reference numerals.

### First Embodiment

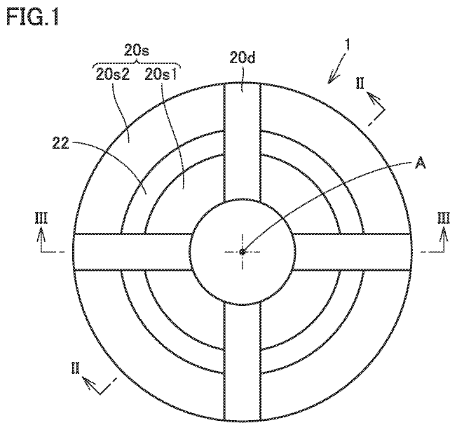

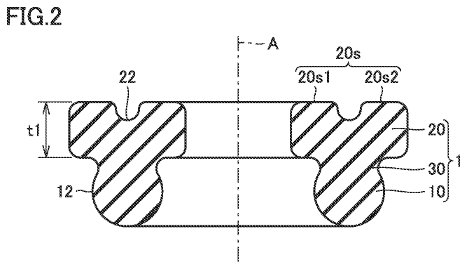

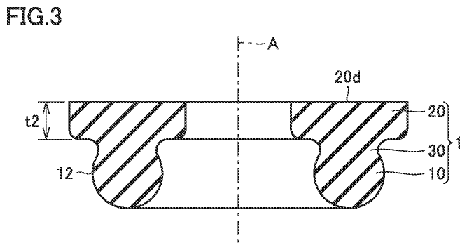

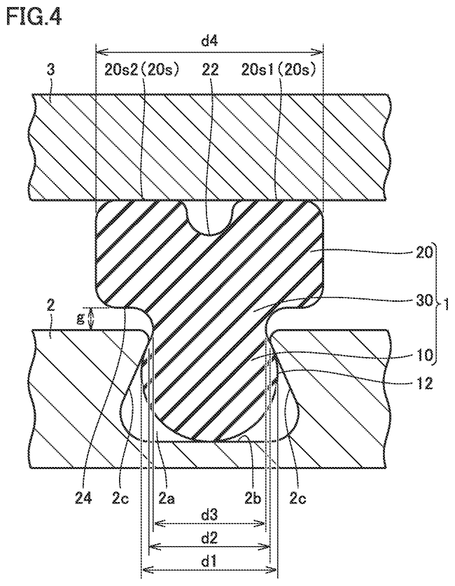

FIG. 1 is a plan view schematically showing a support member in a first embodiment of the present invention. FIG. 2 is a cross-sectional view along a line II-II in FIG. 1. FIG. 3 is a cross-sectional view along a line III-III in FIG. 1. FIG. 4 is a cross-sectional view of the support member and a transport base shown in FIG. 1.

As shown in FIGS. 1 to 4, a support member 1 in the present embodiment is a member to be attached to a transport base 2 for supporting an object 3 to be transported such as wafer. Transport base 2 includes a groove 2a formed in an annular shape. Groove 2a is formed in the shape of the so-called dovetail groove. Specifically, groove 2a has a bottom 2b and a pair of sidewalls 2c. Bottom 2b is formed annularly and flat. The pair of sidewalls 2c is shaped to rise from bottom 2b. Sidewalls 2c are shaped to incline toward each other gradually from bottom 2b toward the opening of the groove.

Support member 1 is attached to groove 2a and, in this state, supports object 3 to be transported. As shown in FIGS. 1 to 3, support member 1 is formed in an annular shape. Support member 1 is made of an elastic material such as fluororubber.

Support member 1 includes a held portion 10, a support portion 20, and a connecting portion 30.

Held portion 10 is a part to be held in groove 2a. Held portion 10 has an external shape larger than the opening of groove 2a. As shown in FIG. 4, held portion 10 includes an expanded portion 12, and dimension d1 of expanded portion 12 in the radial direction of held portion 10 is larger than dimension d2 of the opening of groove 2a in the radial direction. In the present embodiment, in a cross section (the cross section shown in FIG. 4) through a center A (see FIGS. 1 to 3) of support member 1 and orthogonal to support member 1, the external shape of held portion 10 is a circular shape. It should be noted that the external shape of held portion 10 in the orthogonal cross section is not limited to the circular shape. Held portion 10 is pivotable in groove 2a.

Support portion 20 is a part for supporting object 3 to be transported. Support portion 20 is formed in an annular shape. Support portion 20 has a support surface 20s for supporting object 3 to be transported. Support surface 20s is formed by the upper end face of support portion 20. Support surface 20s is formed flat. Support surface 20s is inclined with respect to transport base 2 as held portion 10 is pivoted in groove 2a. In other words, held portion 10 is configured to be pivotable in groove 2a for causing support surface 20s of support portion 20 to incline with respect to transport base 2. Support surface 20s includes an inner support surface 20s1 and an outer support surface 20s2.

Inner support surface 20s1 is a support surface formed inward in the radial direction. Outer support surface 20s2 is a support surface formed outward in the radial direction and coplanar with inner support surface 20s1. In the present embodiment, in the orthogonal cross section, the radial dimension of inner support surface 20s1 is set equal to the radial dimension of outer support surface 20s2.

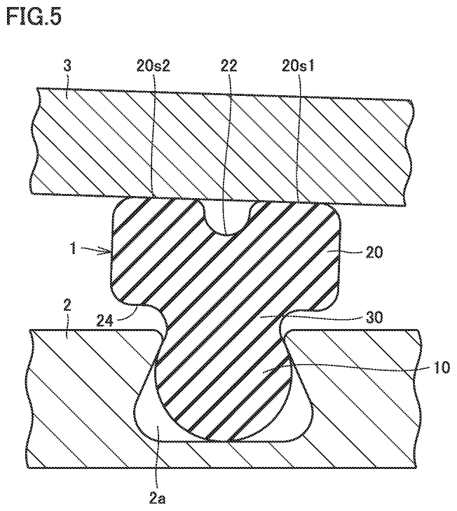

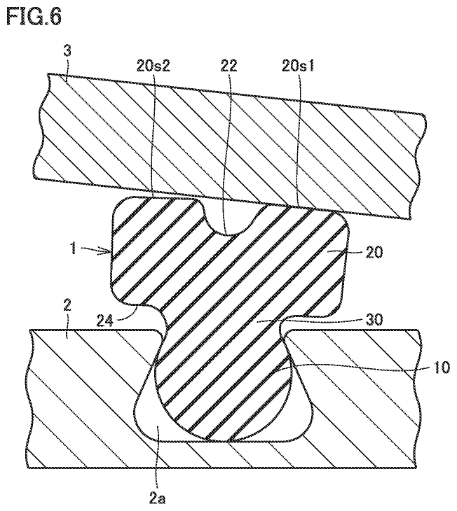

Support portion 20 includes a weak portion 22. Weak portion 22 is formed between inner support surface 20s1 and outer support surface 20s2. As shown in FIGS. 5 and 6, weak portion 22 allows one of inner support surface 20s1 and outer support surface 20s2 to incline with respect to the other of the inner and outer support surfaces. Weak portion 22 includes at least one depressed groove. In the present embodiment, weak portion 22 includes a single depressed groove. The depressed groove is recessed from inner support surface 20s1 and outer support surface 20s2 toward held portion 10, and formed in a shape extending between inner support surface 20s1 and outer support surface 20s2 along the circumferential direction of support portion 20.

As shown in FIG. 4, support portion 20 includes a facing portion 24 that faces transport base 2. Facing portion 24 is formed in parallel with support surface 20s.

As shown in FIGS. 1 and 3, a degassing channel 20d is formed in support surface 20s. Degassing channel 20d is formed in a shape extending from the radially inner end to the radially outer end of support surface 20s. The part of support portion 20 where degassing channel 20d is formed has thickness t2 (see FIG. 3) smaller than thickness t1 (see FIG. 2) of the part of support portion 20 where degassing channel 20d is not formed. Namely, support surface 20s, except for the portion where degassing channel 20d is formed, is formed in an annular shape along the circumferential direction.

Connecting portion 30 is a part connecting held portion 10 to support portion 20 in such a manner that support portion 20 is located at a position separated from transport base 2 with held portion 10 held in groove 2a. In other words, connecting portion 30 is a part that forms a gap g between transport base 2 and facing portion 24.

Connecting portion 30 is elastically deformed to allow support surface 20s of support portion 20 to incline with respect to held portion 10. In the present embodiment, dimension d3 of connecting portion 30 in the radial direction is set smaller than dimension d1 of expanded portion 12 in the radial direction and smaller than dimension d4 of support portion 20 in the radial direction. Dimension d4 of support portion 20 in the radial direction is larger than dimension d1 of expanded portion 12 in the radial direction.

Gap g between facing portion 24 and transport base 2 is determined so as not to allow facing portion 24 to contact transport base 2, in the state where object 3 to be transported inclines toward transport base 2 to contact only one of inner support surface 20s1 and outer support surface 20s2 (the state shown in FIG. 6).

As seen from the foregoing, support member 1 in the present embodiment includes held portion 10 having an external shape larger than the opening of groove 2a. Therefore, held portion 10 is attached into groove 2a to prevent support member 1 from being detached from transport base 2 when object 3 to be transported is inclined with respect to transport base 2. Further, held portion 10 is configured to be pivotable in groove 2a to cause support portion 20 to incline with respect to transport base 2. Therefore, when object 3 to be transported is inclined with respect to transport base 2, support portion 20 is also inclined in accordance with the inclination of object 3 to be transported, to thereby ensure the contact between support member 1 and object 3 to be transported, namely a stable state of supporting object 3 to be transported.

In addition, connecting portion 30 is elastically deformed to allow support portion 20 to incline with respect to held portion 10. Therefore, the ability of support portion 20 to incline in accordance with inclination of object 3 to be transported with respect to transport base 2 is enhanced.

Moreover, support portion 20 includes weak portion 22. Therefore, when object 3 to be transported is inclined with respect to transport base 2, one of inner support surface 20s1 and outer support surface 20s2 also inclines in accordance with the inclination of object 3 to be transported, so as to support object 3 to be transported. Accordingly, the stable state of supporting object 3 to be transported is more reliably ensured.

### Second Embodiment

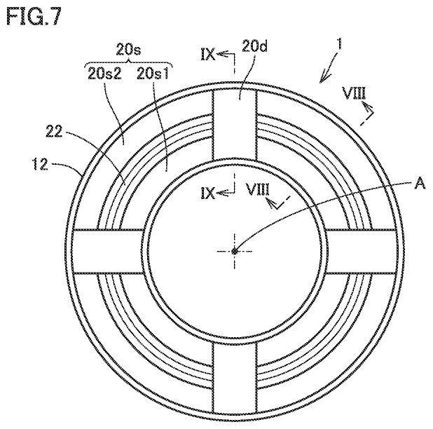

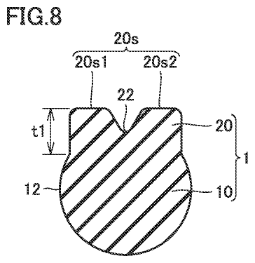

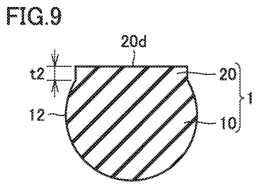

With reference next to FIGS. 7 to 10, a support member 1 in a second embodiment of the present invention is described. In connection with the second embodiment, only those parts and/or features different from the first embodiment are described, and the description of the same structures, functions and advantageous effects as those of the first embodiment is not repeated.

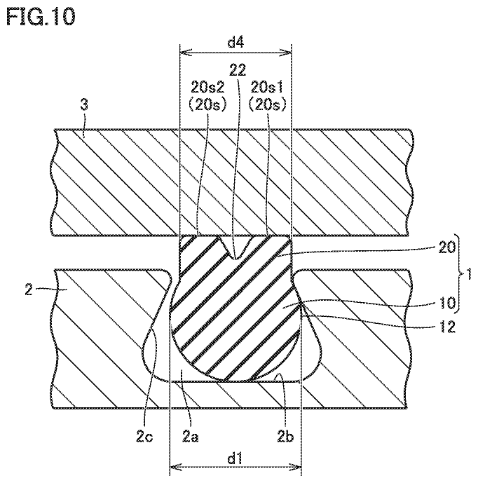

In the present embodiment, support member 1 includes a held portion 10 and a support portion 20 only. The shape of held portion 10 is identical to that of the first embodiment. Support portion 20 connects to the upper end of held portion 10. As shown in FIG. 10, dimension d4 of support portion 20 in the radial direction is smaller than dimension d1 of an expanded portion 12 in the radial direction. In this embodiment, the radial dimension of support member 1 is smaller than that of the first embodiment.

It should be construed that the embodiments disclosed herein are given by way of illustration in all respects, rather than limitation. The scope of the present invention is defined by claims, rather than the above description of the embodiments, and encompasses all modifications equivalent in meaning and scope to the claims.

For example, in the first embodiment, connecting portion 30 may be made of a material having a smaller hardness than the hardness of held portion 10 and the hardness of support portion 20.

Moreover, the structure of weak portion 22 is not limited to the example presented in the above embodiments. Weak portion 22 may be varied as long as weak portion 22 allows one of inner support surface 20s1 and outer support surface 20s2 to incline with respect to the other support surface. For example, weak portion 22 may be formed of a plurality of depressed grooves that are arranged concentrically.

Moreover, degassing channel 20d may not be formed. In this case, support surface 20s and the depressed groove are formed continuously in an annular shape.

It will be understood by those skilled in the art that a plurality of exemplary embodiments described above may be implemented specifically in the following manners.

The support member in the above-described embodiments is a support member attachable to a groove formed in an annular shape in a transport base, and the support member is to be attached to the groove for supporting an object to be transported. The support member includes: a held portion to be held in the groove; and a support portion formed in an annular shape for supporting the object to be transported at a position separated from the transport base with the held portion held in the groove. The held portion is pivotable in the groove to cause the support portion to incline with respect to the transport base.

In this support member, the held portion is configured to be pivotable in the groove to allow the support portion to incline with respect to the transport base. Therefore, when the object to be transported is inclined with respect to the transport base, the support portion is also inclined in accordance with the inclination of the object to be transported, to thereby ensure the contact between the support member and the object to be transported, namely a stable state of supporting the object to be transported.

Preferably, the held portion has an external shape larger than an opening of the groove.

Accordingly, the held portion is attached into the groove to prevent the support member from being detached from the transport base when the object to be transported is inclined with respect to the transport base.

Preferably, an external shape of the held portion is formed in a circular shape in a cross section through a center of the support portion and orthogonal to the support portion.

Accordingly, the held portion is pivoted smoothly in the groove.

The support member may further include a connecting portion connecting the held portion to the support portion. In this case, preferably the connecting portion is elastically deformed to allow the support portion to incline with respect to the held portion.

In this embodiment, the connecting portion is elastically deformed to allow the support portion to incline with respect to the held portion. Therefore, the ability of the support portion to incline in accordance with inclination of the object to be transported with respect to the transport base is enhanced.

The held portion may include an expanded portion, and a dimension of the expanded portion in a radial direction of the held portion is larger than that of an opening of the groove. In this case, preferably a dimension of the connecting portion in the radial direction is smaller than the dimension of the expanded portion in the radial direction and smaller than a dimension of the support portion in the radial direction.

Accordingly, the advantageous effects described above are obtained effectively. Alternatively, a dimension of the support portion in the radial direction may be smaller than the dimension of the expanded portion in the radial direction.

In this embodiment, the radial dimension of the support member can be reduced.

Preferably, the support portion has a support surface to support the object to be transported, the support surface includes: an inner support surface formed inward in a radial direction of the support portion; and an outer support surface formed outward in the radial direction of the support portion and coplanar with the inner support surface, and the support portion includes a weak portion formed between the inner support surface and the outer support surface for allowing one of the inner support surface and the outer support surface to incline with respect to the other of the inner support surface and the outer support surface.

Accordingly, when the object to be transported is inclined with respect to the transport base, one of the inner support surface and the outer support surface is inclined in accordance with the inclination of the object to be transported, and therefore, a stable state of supporting the object to be transported is more reliably ensured.

Preferably, the weak portion includes at least one depressed groove, and the at least one depressed groove is recessed from the inner support surface and the outer support surface toward the held portion, and formed in a shape extending between the inner support surface and the outer support surface along a circumferential direction of the support portion.

In this way, the above-described advantageous effects are effectively obtained.

What is claimed is:

1. A support member attachable to a groove formed in an annular shape in a transport base, the support member being to be attached to the groove for supporting an object to be transported, the support member comprising:
a held portion to be held in the groove; and
a support portion formed in an annular shape for supporting the object to be transported at a position separated from the transport base with the held portion held in the groove,
the held portion being pivotable in the groove to cause the support portion to incline with respect to the transport base.

2. The support member according to claim 1, wherein the held portion has an external shape larger than an opening of the groove.

3. The support member according to claim 1, wherein an external shape of the held portion is formed in a circular shape in a cross section through a center of the support portion and orthogonal to the support portion.

4. The support member according to claim 1, further comprising a connecting portion connecting the held portion to the support portion, wherein
the connecting portion is elastically deformed to allow the support portion to incline with respect to the held portion.

5. The support member according to claim 4, wherein
the held portion includes an expanded portion, and a dimension of the expanded portion in a radial direction of the held portion is larger than that of an opening of the groove, and
a dimension of the connecting portion in the radial direction is smaller than the dimension of the expanded portion in the radial direction and smaller than a dimension of the support portion in the radial direction.

6. The support member according to claim 1, wherein
the held portion includes an expanded portion, and a dimension of the expanded portion in a radial direction of the held portion is larger than that of an opening of the groove, and
a dimension of the support portion in the radial direction is smaller than the dimension of the expanded portion in the radial direction.

7. The support member according to claim 1, wherein
the support portion has a support surface to support the object to be transported,
the support surface includes:
an inner support surface formed inward in a radial direction of the support portion; and
an outer support surface formed outward in the radial direction of the support portion and coplanar with the inner support surface, and
the support portion includes a weak portion formed between the inner support surface and the outer support surface for allowing one of the inner support surface and the outer support surface to incline with respect to the other of the inner support surface and the outer support surface.

8. The support member according to claim 7, wherein
the weak portion includes at least one depressed groove, and
the at least one depressed groove is recessed from the inner support surface and the outer support surface toward the held portion, and formed in a shape extending between the inner support surface and the outer support surface along a circumferential direction of the support portion.
